(19) United States
(12) Patent Application Publication
(10) Pub. No.: US 2024/0339552 A1
(43) Pub. Date: Oct. 10, 2024

(54) Low-noise avalanche photodetector

(71) Applicants: Tomislav Suligoj, Zagreb (HR); Ivan Berdalovic, Zagreb (HR); Borna Pozar, Karlovac (HR)

(72) Inventors: Tomislav Suligoj, Zagreb (HR); Ivan Berdalovic, Zagreb (HR); Borna Pozar, Karlovac (HR)

(21) Appl. No.: 18/628,359

(22) Filed: Apr. 5, 2024

Related U.S. Application Data
(60) Provisional application No. 63/457,797, filed on Apr. 7, 2023.

(51) Int. Cl. H01L 31/107; H01L 27/146

(52) U.S. Cl. CPC H01L 31/107; H01L 27/14643; H01L 27/14689

(57) ABSTRACT

A photodetector includes a first well region having a first conductivity type, extending into a semiconductor substrate to a first depth from a top surface of the semiconductor substrate; a second well region having a second conductivity type, extending into the semiconductor substrate from the first depth to a second depth larger than the first depth, forming an active metallurgical p-n junction with the first well region, a buried layer having a second conductivity type, forming an isotype metallurgical junction with the second well region at a distance D from the top surface, wherein the active metallurgical p-n junction produces an electric field having a maximum positioned between 0.2D and 0.8D when measured from the top surface.

### REFERENCE TO RELATED APPLICATIONS

This application is based on and claims priority to U.S. Provisional Application Ser. No. 63/457,797, filed on Apr. 7, 2023, which is hereby incorporated by reference as if set forth in full in this application for all purposes.

### BACKGROUND OF THE INVENTION

A semiconductor photodetector capable of detecting low-intensity light is required in a plurality of applications. In particular, an avalanche photodiode (APD) is well-suited for said applications, since the avalanche multiplication of charge carriers generated by absorption of light can provide a higher electrical signal at the output of said APD compared to a conventional p-i-n photodiode. If said APD is operated at a reverse bias voltage above its breakdown voltage by some excess voltage, in Geiger mode, a single charge carrier can trigger a self-sustaining avalanche multiplication process, thereby enabling the detection of a single photon with a certain probability. An APD operated in Geiger mode is henceforth referred to as a single-photon avalanche diode (SPAD).

Some of the key considerations in the design of said SPAD are the photon detection probability (PDP), which describes the sensitivity of the device to incident light (the same as photon detection efficiency (PDE), just without losses in the peripheral regions of device), and the dark count rate (DCR), which represents the number of detections per unit time in the absence of light, typically caused by thermally generated charge carriers, and describes the noise performance of the device. A plurality of solutions has been proposed to optimize the PDP and DCR, most of which require fully customized technologies and methods of manufacturing. Said fully customized SPADs can achieve a peak PDP nearing 70% and a DCR below 1 Hz per micrometer square of detector area at room temperature. For light detection in the visible and near-infrared range, silicon SPADs fabricated using commercial complementary metal-oxide-semiconductor (CMOS) technology methods of manufacturing have been demonstrated, offering significant benefits in terms of manufacturing costs and integration possibilities with associated electronic circuitry compared with their fully customized counterparts. However, the optimization of PDP and efficiency is hindered by inherent limitations within the CMOS process flow pertaining to a restricted number of available well regions and doping concentrations that are required for standard CMOS electronic device manufacturing. For example, if a typical shallow source/drain region and an underlying well region are used to form the active metallurgical p-n junction of the device, which produces an electric field providing multiplication of charge carriers, the PDP is degraded because a significant portion of the incident light is absorbed outside the depletion region formed around said active p-n junction, especially at wavelengths of incident light penetrating deep into the silicon substrate, such as the red and near-infrared part of the spectrum. Concurrently, the DCR is impaired by the proximity of surface and interface defects to said active p-n junction, as well as charge carrier tunneling between the highly doped regions, and can reach values of several kHz per micrometer square at room temperature. The challenge is in developing a suitable SPAD structure that would be compatible with and can be integrated with a CMOS process yet producing high PDP and low DCR.

To overcome some of said limitations, CMOS-integrated SPAD developments have focused on high-voltage CMOS technologies, which offer a larger number of well regions and a wider range of doping concentrations compared with their low-voltage counterparts, while retaining the cost and integration benefits of the latter. In particular, the availability of multiple deep well regions with low doping concentrations allows moving the active metallurgical p-n junction as deep as possible into the silicon substrate to improve PDP, especially at longer wavelengths within the visible spectrum, as well as improving DCR, since said deeper p-n junction is formed far from surface defects which would otherwise have a significant contribution to the DCR. This type of optimization is described in numerous publicly available texts, such as L. D. Huang et al., “Single-photon avalanche diodes in 0.18-μm high-voltage CMOS technology,” Opt. Express, vol. 25, no. 12, pp. 13333-13339, 2017.

FIG. 1 illustrates a cross-sectional view of a photodetector according to prior art in this field. With reference to FIG. 1, the active p-n junction 171 is formed between a first well region 113 having a p-type conductivity, extending deep into a monocrystalline silicon substrate 101 from a top surface of said silicon substrate, and a buried layer 221 having an n-type conductivity, substantially distant from said top surface. A second well region 214 having an n-type conductivity extending deep into said silicon substrate from said top surface forms a metallurgical junction of the same conductivity type (henceforth referred to as an isotype metallurgical junction) with said buried layer 221. A first electrode region 131 having a p-type conductivity and a substantially higher doping concentration than said first well region 113 is placed within said first well region 113 and electrically coupled to a first contact region 141. A second electrode region 232 having an n-type conductivity and a substantially higher doping concentration than said second well region 214 is placed within said second well region 214 and electrically coupled to a second contact region 242. A first insulating region 151 is placed between said first electrode region 131 and said second electrode region 232, and a second insulating region 152 extends laterally from said second electrode region 232 towards said silicon substrate 101.

With reference to FIG. 1, a depletion region is formed between said first electrode region 131 and said buried layer 221, providing a wide layer to absorb incident light. The electric field profile within said depletion region is such that photons absorbed above said active p-n junction 171 generate electron-hole pairs, where photogenerated electrons drift towards said active p-n junction. The same applies to thermally generated electrons. Applying a high negative bias voltage between said first contact region 141 and said second contact region 242 results in avalanche multiplication of charge carriers in the vicinity of the electric field maximum positioned near said active p-n junction 171. Since the ionization coefficient for electrons in silicon is substantially higher than the ionization coefficient for holes, when the device is operated in Geiger mode, electrons cause the majority of avalanche multiplication events under illumination from said top surface, leading to a high peak PDP of around 20% at a wavelength of 580 nm. However, thermally generated electrons are also the dominant charge carrier type contributing to avalanche events in the absence of light, leading to a DCR above 1 Hz per micrometer square at room temperature. With said active p-n junction placed shallower within said depletion region, holes with a lower ionization coefficient thermally generated below said active p-n junction would have a more significant contribution to avalanche events without illumination, leading to an improvement in DCR. Therefore, if low noise is a critical requirement for the operation of a silicon SPAD in a certain application, moving said active p-n junction closer to said top surface with respect to said buried layer 221, but keeping it far enough from said top surface to minimize the contribution of surface defects, would be beneficial for minimizing the DCR.

### BRIEF DESCRIPTION OF THE INVENTION

The present disclosure offers a photodetector wherein the arrangement of well regions within a semiconductor substrate provides a medium-depth active p-n junction as a layer for charge carrier multiplication, which is sufficiently distant from the semiconductor surface and associated interface defects, while it produces an electric field profile causing the carrier type with a lower ionization coefficient to have a non-negligible contribution to avalanche events without illumination. These modifications result in an ultra-low DCR, well below 1 Hz per micrometer square. At the same time, the improved photodetector retains a high PDP even in the red part of the visible spectrum due to a wide depletion region, but particularly at shorter wavelengths penetrating only above said active p-n junction, since at these wavelengths, the carrier type with a higher ionization coefficient would cause the majority of avalanche multiplication events under illumination. Said well regions may be manufactured using a high-voltage CMOS technology method of manufacturing, offering low cost and high integration density along with high performance in terms of detection probability and noise.

According to one or more embodiments of the invention, there is provided a photodetector which includes a semiconductor substrate, which may be monocrystalline silicon; a first well region having a first conductivity type extending into said semiconductor substrate to a first depth from a top surface of said semiconductor substrate; a second well region having a second conductivity type, extending into said semiconductor substrate from said first depth to a second depth larger than said first depth, forming an active metallurgical p-n junction with said first well region; a buried layer having a second conductivity type, substantially distant from said top surface, forming an isotype metallurgical junction with said second well region at a distance D from said top surface; wherein said active metallurgical p-n junction produces an electric field having a maximum positioned between 0.2D and 0.8D when measured from said top surface;

Said active metallurgical p-n junction may produce an electric field which provides multiplication of charge carriers.

Said photodetector may further include a third well region having a first conductivity type, extending into said semiconductor substrate from said top surface to a third depth larger than said first depth, surrounding and overlapping with a portion of said first well region, and forming a passive metallurgical p-n junction with said buried layer;

Said photodetector may further include a fourth well region having a second conductivity type, extending into said semiconductor substrate from said top surface to a fourth depth larger than said first depth, surrounding said third well region, and forming an isotype metallurgical junction with said buried layer;

Said photodetector may have a semiconductor substrate of a first conductivity type, forming a passive metallurgical p-n junction with said buried layer.

Said photodetector may have a semiconductor substrate of a second conductivity type, forming an isotype metallurgical junction with said buried layer, wherein said buried layer may have a doping concentration substantially equal to said semiconductor substrate.

Said photodetector may further include a first electrode region having a first conductivity type, placed within said first well region and electrically coupled to a first contact region.

Said photodetector may further include a second electrode region having a second conductivity type, placed within said fourth well region and electrically coupled to a second contact region.

Said photodetector may further include an insulating region, which may be silicon dioxide, placed between said first electrode region and said second electrode region.

Said photodetector may further include a layered structure region, which may comprise a polycrystalline silicon layer on top of an insulating layer, formed on said top surface between said first electrode region and said second electrode region, and which may be electrically coupled to said first electrode region.

Said photodetector may be manufactured using a high-voltage CMOS technology, simultaneously with CMOS transistors, wherein said first electrode region and said second electrode region may be manufactured as source/drain regions, said first well region may be manufactured as a medium-voltage well region, said second well region, said third well region and said fourth well region may be manufactured as high-voltage well regions, said buried layer may be manufactured as a buried layer, said insulating region may be manufactured as a shallow trench isolation (STI) region, and said layered structure region may be manufactured as a gate polycrystalline silicon layer on top of a gate oxide layer, all being part of said high-voltage CMOS technology.

### BRIEF DESCRIPTION OF THE DRAWINGS

Aspects of the present disclosure are best understood by reference to the following detailed description when read with the accompanying drawings, in which:

FIG. 1 illustrates a cross-sectional view of a photodetector according to prior art in this field;

FIGS. 2-5 illustrate cross-sectional views of a photodetector according to some embodiments of the invention;

FIG. 6 illustrates a cross-sectional view of simulated electric field within the right half of the photodetector from FIG. 1 (SPAD A);

FIG. 7 illustrates a cross-sectional view of simulated electric field within the right half of an embodiment of the photodetector from FIG. 5 (SPAD B);

FIG. 8 illustrates a simulated one-dimensional electric field profile along the vertical direction within the central regions of the photodetectors from FIG. 6 (SPAD A) and FIG. 7 (SPAD B);

FIG. 9 illustrates the simulated avalanche probability due to the multiplication of electrons and holes within the central regions of the photodetectors from FIG. 6 (SPAD A) and FIG. 7 (SPAD B);

FIG. 10 illustrates the simulated and measured DCR for the photodetectors from FIG. 6 (SPAD A) and FIG. 7 (SPAD B);

FIG. 11 illustrates the simulated and measured PDP for the photodetectors from FIG. 6 (SPAD A) and FIG. 7 (SPAD B);

FIG. 12 illustrates a cross-sectional view of a photodetector according to an embodiment of the invention;

FIGS. 13-14 illustrate plan views of the photodetector from FIG. 4 according to some embodiments of the invention;

FIGS. 15-19 illustrate cross-sectional views of a photodetector according to some embodiments of the invention;

FIGS. 20-21 illustrate plan views of the photodetector from FIG. 17 according to some embodiments of the invention;

### DETAILED DESCRIPTION OF THE INVENTION

The present disclosure will now be described by reference to embodiments, examples of which are illustrated in the accompanying drawings, wherein like reference numerals are used to denote like elements throughout. It will be appreciated that said elements are not necessarily drawn to scale, and that dimensions of said elements may be arbitrarily increased or reduced for clarity of discussion.

The embodiments described herein are merely examples and are not intended to limit the scope of the present disclosure. It will be understood by those ordinary skilled in the art that various modifications can be made to the described embodiments without departing from the spirit and scope of the present disclosure.

Spatially relative terms such as “above”, “below”, “top”, “bottom” and the like, may be used herein to describe the relationship of one element to another, as illustrated in the accompanying drawings. It will be understood that the spatially relative terms are intended to encompass different orientations of the device in addition to the orientation depicted in the drawings. The device may be otherwise oriented (e.g., rotated by 90 degrees) and the spatially relative descriptors used herein should be interpreted accordingly.

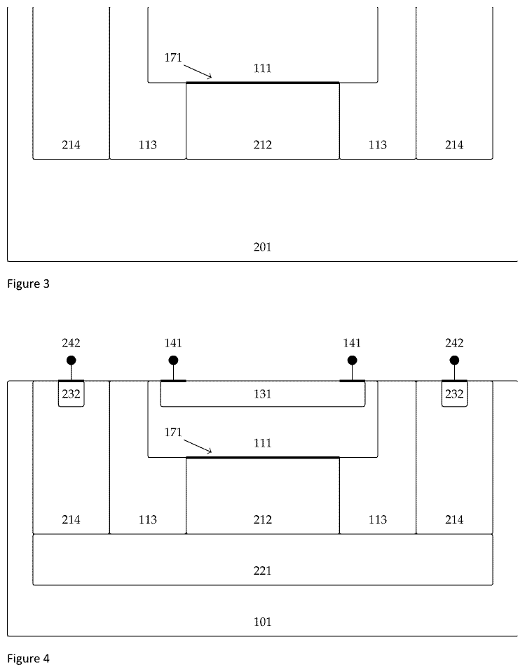

FIG. 2 illustrates a cross-sectional view of a photodetector according to an embodiment. With reference to FIG. 2, a photodetector may be provided, which may include a semiconductor substrate 101. The material of said semiconductor substrate may be, but is not limited to, monocrystalline silicon. The conductivity type of said semiconductor substrate may be p-type. A first well region 111 may extend into said semiconductor substrate to a first depth from a top surface of said semiconductor substrate. The conductivity type of said first well region 111 may be p-type. A second well region 212 may extend into said semiconductor substrate from a bottom boundary of said first well region 111 to a second depth larger than said first depth. The conductivity type of said second well region 212 may be n-type, forming an active metallurgical p-n junction 171 with said first well region 111. A buried layer 221 may be formed in said semiconductor substrate substantially distant from said top surface. The conductivity type of said buried layer 221 may be n-type, forming an isotype metallurgical junction with said second well region 212 at a distance D from said top surface.

Said photodetector may further include a third well region 113, extending into said semiconductor substrate from said top surface to a third depth larger than said first depth, surrounding and overlapping with a portion of said first well region 111. The conductivity type of said third well region 113 may be p-type, forming an isotype metallurgical junction with said first well region 111, forming a passive metallurgical p-n junction with said buried layer 221, and forming a passive metallurgical p-n junction substantially perpendicular to said top surface with said second well region 212. The doping concentration of said first well region 111 may be substantially higher than the doping concentration of said third well region 113. A fourth well region 214 may extend into said semiconductor substrate from said top surface to a fourth depth larger than said first depth, surrounding said third well region 113. The conductivity type of said fourth well region 214 may be n-type, forming an isotype metallurgical junction with said buried layer 221, and forming a passive metallurgical p-n junction substantially perpendicular to said top surface with said third well region 113.

FIG. 3 illustrates a cross-sectional view of a photodetector according to an embodiment. With reference to FIG. 3, a photodetector may be provided, which may include a semiconductor substrate 201. The conductivity type of said semiconductor substrate may be n-type. Analogous to the elements of the photodetector illustrated in FIG. 2, a first well region 111, the conductivity type of which may be p-type, a second well region 212, the conductivity type of which may be n-type, a third well region 113, the conductivity type of which may be p-type, and a fourth well region 214, the conductivity type of which may be n-type, may be formed in said semiconductor substrate, wherein said second well region 212 may form an active metallurgical p-n junction 171 with said first well region 111. In this embodiment, the buried layer of the photodetector illustrated in FIG. 2 may have the same conductivity type and same doping concentration as the semiconductor substrate 201, and is therefore omitted from the drawing.

FIG. 4 illustrates a cross-sectional view of a photodetector according to an embodiment. With reference to FIG. 4, a photodetector may be provided, which may include a first electrode region 131 placed within said first well region 111 and electrically coupled to a first metal contact region 141, in addition to the elements of the photodetector illustrated in FIG. 2. The conductivity type of said first electrode region 131 may be p-type, forming an isotype metallurgical junction with said first well region 111. The doping concentration of said first electrode region 131 may be substantially higher than the doping concentration of said first well region 111.

Said photodetector may further include a second electrode region 232 placed within said fourth well region 214 and electrically coupled to a second metal contact region 242, in addition to the elements of the photodetector illustrated in FIG. 2. The conductivity type of said second electrode region 232 may be n-type, forming an isotype metallurgical junction with said fourth well region 214. The doping concentration of said second electrode region 232 may be substantially higher than the doping concentration of said fourth well region 214.

FIG. 5 illustrates a cross-sectional view of a photodetector according to an embodiment. With reference to FIG. 5, a photodetector may be provided, which may include a first insulating region 151 placed between said first electrode region 131 and said second electrode region 232, and a second insulating region 152, extending laterally from said second electrode region 232 towards said semiconductor substrate 101, in addition to the elements of the photodetector illustrated in FIG. 5. The material of said insulating regions 151 and 152 may be, but is not limited to, silicon dioxide.

Applying a negative bias voltage between said first contact region 141 and said second contact region 242 may result in a reverse bias voltage between elements having a p-type conductivity (111, 113 and 131) and elements having an n-type conductivity (212, 214, 221 and 232), which may result in an active depletion region being formed between said first electrode region 131 and said buried layer 221. Said active depletion region may extend from the bottom of said first electrode region 131 to the top of said buried layer 221, and may provide a layer having a function of absorbing incident light. Photons absorbed above said active metallurgical p-n junction 171 may generate electron-hole pairs, where the photogenerated electrons may drift towards said active metallurgical p-n junction under the influence of the electric field within said active depletion region. The same may apply to thermally generated electrons. Photons absorbed below said active metallurgical p-n junction 171 may generate electron-hole pairs, where the photogenerated holes may drift towards said active metallurgical p-n junction under the influence of the electric field within said active depletion region. The same may apply to thermally generated holes.

Applying a high enough negative bias voltage between said first contact region 141 and said second contact region 242 may result in avalanche multiplication of charge carriers in the vicinity of the electric field maximum positioned near said active metallurgical p-n junction 171. The applied negative bias voltage may result in a reverse bias voltage higher than the breakdown voltage of said active metallurgical p-n junction, and said photodetector may operate in Geiger mode.

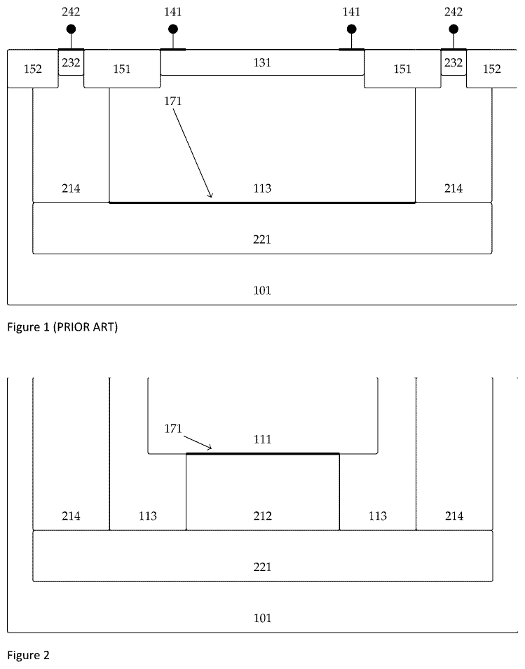

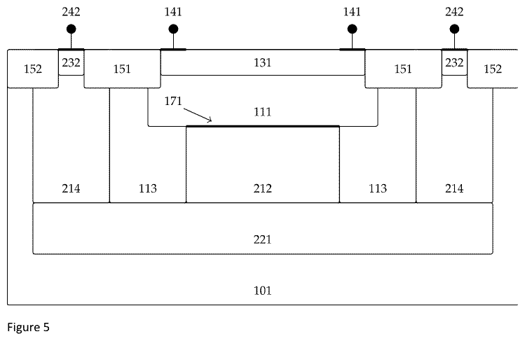

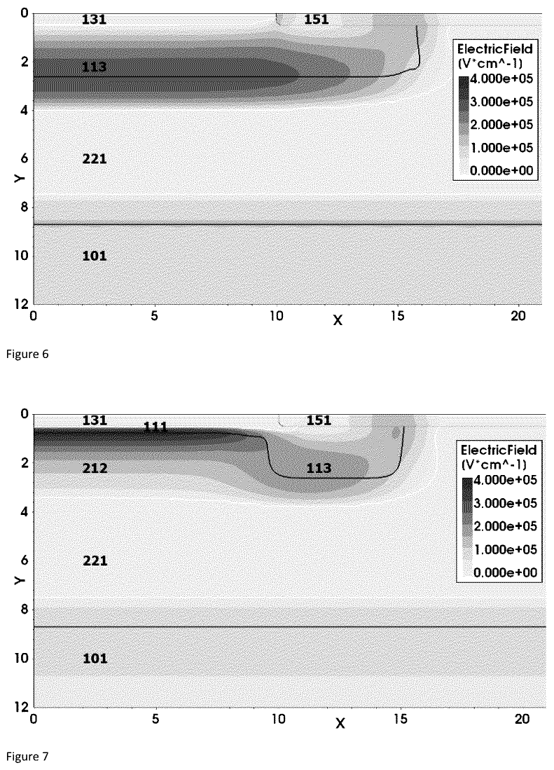

With reference to FIG. 5, it can be seen that said active metallurgical p-n junction 171 of the photodetector is positioned at a distance from said top surface which is substantially smaller compared with the photodetector according to prior art illustrated in FIG. 1. This may result in a vertical electric field profile wherein the maximum of said electric field is positioned substantially closer to said top surface than the top boundary of said buried layer, unlike the photodetector from FIG. 1, wherein the electric field maximum is positioned at a distance approximately equal to D from said top surface. This is demonstrated by simulated two-dimensional electric field distributions for two exemplary photodetectors, both implemented in the same 180 nm high-voltage CMOS technology, as illustrated in FIGS. 6-7.

FIG. 6 illustrates a cross-sectional view of simulated electric field within the right half of the photodetector from FIG. 1 (henceforth denoted as SPAD A).

FIG. 7 illustrates a cross-sectional view of simulated electric field within the right half of an embodiment of the photodetector from FIG. 5 (henceforth denoted as SPAD B).

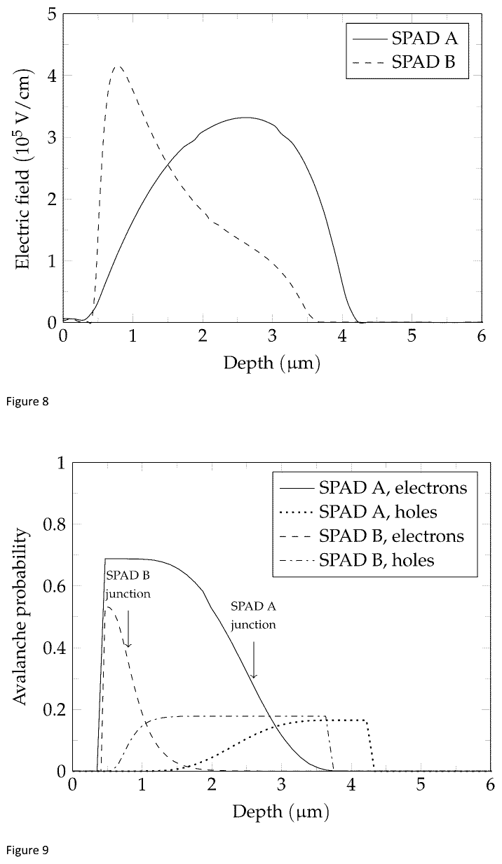

FIG. 8 illustrates a simulated one-dimensional electric field profile along the vertical direction within the central regions of the photodetectors from FIG. 6 (SPAD A) and FIG. 7 (SPAD B). With reference to FIG. 8, a substantial difference in electric field profile within the two devices can be seen. Said electric field maximum is positioned at a distance of around 2.6 μm from said top surface in SPAD A, whereas said electric field maximum is positioned at a distance of around 0.8 μm from said top surface in SPAD B.

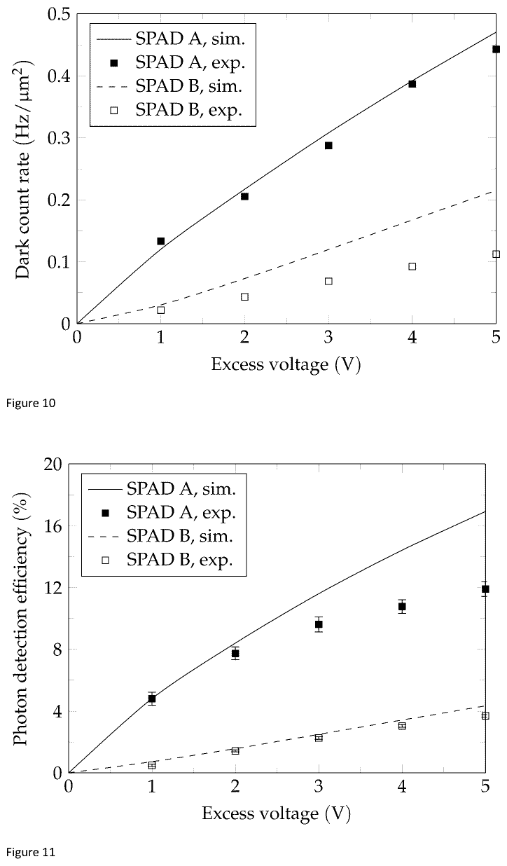

FIG. 9 illustrates the simulated avalanche probability due to the multiplication of electrons and holes within the central regions of the photodetectors from FIG. 6 (SPAD A) and FIG. 7 (SPAD B). With reference to FIG. 9, it can be seen that SPAD A features a wide region having a high avalanche probability for electrons, above the region of said electric field maximum. Electrons generated within said high-avalanche-probability region may cause the majority of avalanche multiplication events under illumination. For a semiconductor material wherein the ionization coefficient for electrons is substantially higher than the ionization coefficient for holes (e.g., monocrystalline silicon), this may result in a high PDP. Electrons thermally generated within said high-avalanche-probability region may also cause the majority of avalanche multiplication events in the absence of light, which may result in a high DCR.

With reference to FIG. 9, it can be seen that SPAD B features a wide region having a high avalanche probability for holes, below the region of said electric field maximum. Holes generated within said high-avalanche-probability region may cause the majority of avalanche multiplication events under illumination with a long-wavelength light having a long penetration depth. For a semiconductor material wherein the ionization coefficient for holes is substantially lower than the ionization coefficient for electrons (e.g., monocrystalline silicon), this may result in a substantially lower PDP compared with SPAD A at said long wavelength. However, electrons may still cause the majority of avalanche multiplication events under illumination with a short-wavelength light having a short penetration depth from said top surface, which may result in a PDP comparable to that of SPAD A at said short wavelength. Holes thermally generated within said high-avalanche-probability region may also cause the majority of avalanche multiplication events in the absence of light, which may result in a substantially lower DCR compared with SPAD A.

With reference to FIG. 5, wherein the isotype metallurgical junction between said buried layer 221 and said second well region 212 is positioned at a distance D from said top surface, said electric field maximum should be positioned at a distance no higher than 0.8D from said top surface for holes to have a non-negligible contribution to avalanche multiplication events without illumination. Concurrently, with D approximately equal to 2.6 μm in a typical 180 nm high-voltage CMOS technology, said electric field maximum should be positioned at a distance higher than 0.2D from said top surface to minimize the impact of defects which may be present at the boundaries of said insulating region 151. This provides the range of values for the distance of said electric field maximum from said top surface to achieve a minimal DCR.

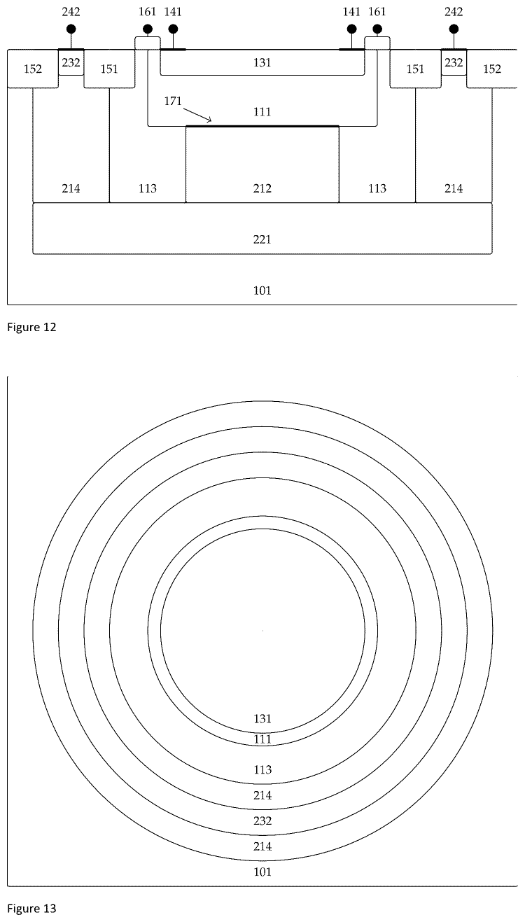

FIG. 10 illustrates the simulated and measured DCR for the photodetectors from FIG. 6 (SPAD A) and FIG. 7 (SPAD B). With reference to FIG. 10, it can be seen that a dark count rate (DCR) lower than 0.25 Hz per micrometer square can readily be achieved at an excess voltage of 5 V and at a temperature of 300 K for a photodetector of a present disclosure (SPAD B). It can also be seen that SPAD B exhibits a simulated and measured room-temperature DCR substantially lower compared with SPAD A, by around a factor of 4 as measured at an excess voltage of 5 V.

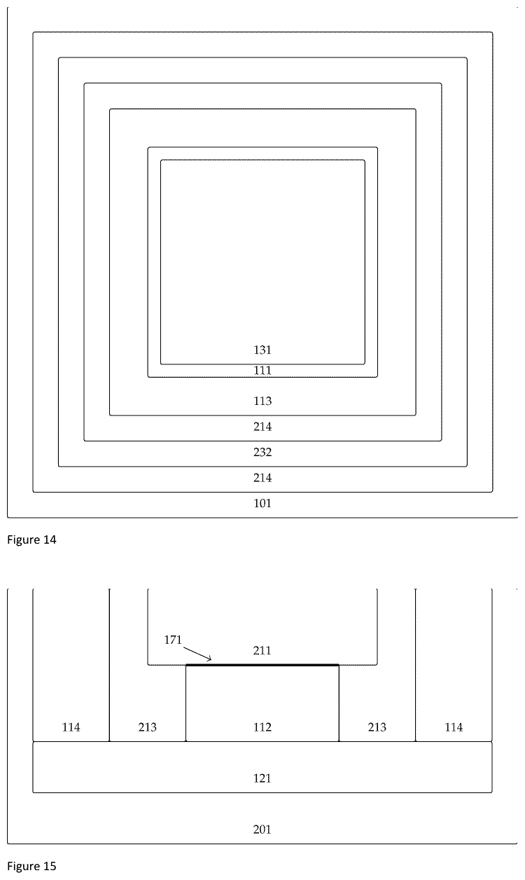

FIG. 11 illustrates the simulated and measured PDP for the photodetectors from FIG. 6 (SPAD A) and FIG. 7 (SPAD B). With reference to FIG. 11, it can be seen that SPAD B exhibits a simulated and measured PDP substantially lower compared with SPAD A at a wavelength of 660 nm, by around a factor of 3 as measured at an excess voltage of 5 V. The difference in PDP between the two devices may be substantially smaller at shorter wavelengths of incident light.

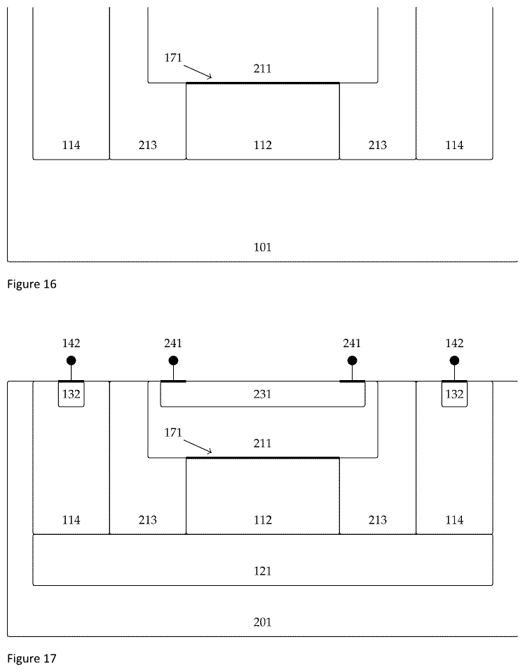

FIG. 12 illustrates a cross-sectional view of a photodetector according to an embodiment. With reference to FIG. 12, a photodetector may be provided, which may include a layered structure region 161 formed on said top surface between said first electrode region 131 and said second electrode region 232, in addition to the elements of the photodetector illustrated in FIG. 5. Said layered structure region 161 may comprise, but is not limited to, a polycrystalline silicon layer on top of a silicon dioxide layer. Said layered structure region 161 may be electrically coupled to said first electrode region 131. Said first insulating region 151 may be removed beneath said layered structure region 161.

With reference to FIG. 12, elements of said photodetector may be manufactured using a well-established high-voltage CMOS technology, simultaneously with CMOS transistors, on an p-type monocrystalline silicon substrate 101. Said first electrode region 131 may be manufactured as a p+ source/drain region, said second electrode region 232 may be manufactured as an n+ source/drain region, said first well region 111 may be manufactured as a medium-voltage p-well region (e.g., a 5-V p-well region in a 180 nm high-voltage CMOS technology with a nominal supply voltage of 1.8 V), said second well region 212 may be manufactured as a high-voltage n-well region, said buried layer 221 may be manufactured as an n-type buried layer, said third well region 113 may be manufactured as a high-voltage p-well region, said fourth well region 214 may be manufactured as a high-voltage n-well region, said insulating regions 151 and 152 may be manufactured as shallow trench isolation (STI) regions, and said layered structure region 161 may be manufactured as a gate polycrystalline silicon layer on top of a gate oxide layer, all being part of said high-voltage CMOS technology method of manufacturing. Said first contact region 141 and said second contact region 242 may be electrically coupled to a metal layer being part of said high-voltage CMOS technology method of manufacturing.

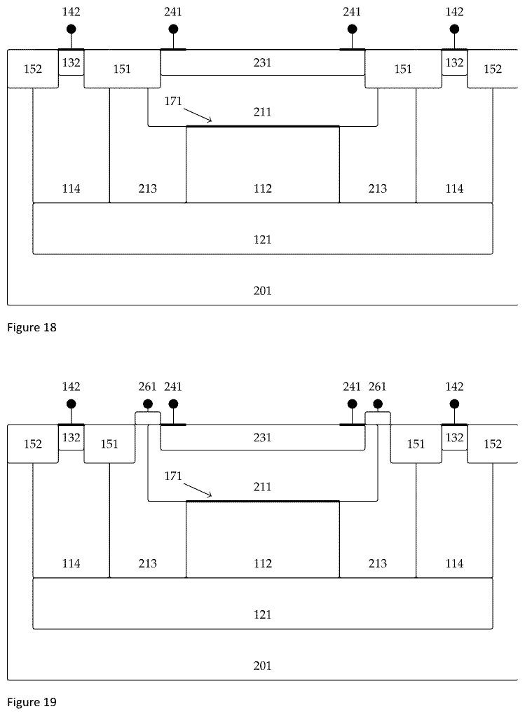

FIG. 13 illustrates a plan view of the photodetector from FIG. 4 according to an embodiment. With reference to FIG. 13, said first well region 111 and said first electrode region 131 may have a circular shape, whereas said third well region 113, said fourth well region 214 and said second electrode region 232 may have a circular annular shape.

FIG. 14 illustrates a plan view of the photodetector from FIG. 4 according to an embodiment. With reference to FIG. 14, said first well region 111 and said first electrode region 131 may have a square shape, whereas said third well region 113, said fourth well region 214 and said second electrode region 232 may have a square annular shape.

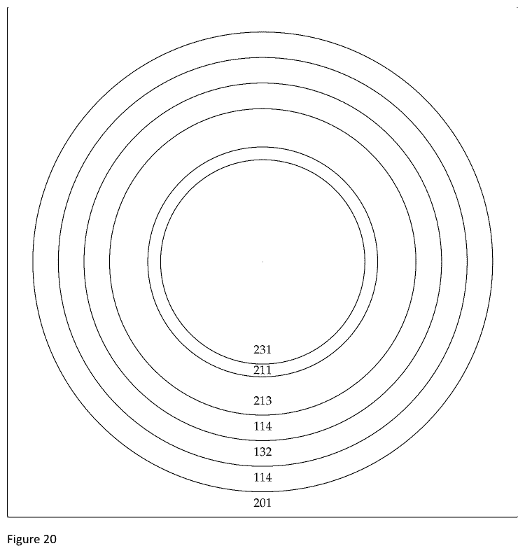

FIG. 15 illustrates a cross-sectional view of a photodetector according to an embodiment. With reference to FIG. 15, a photodetector may be provided, which may include a semiconductor substrate 201. The conductivity type of said semiconductor substrate may be n-type. Analogous to the elements of the photodetector illustrated in FIG. 2, a first well region 211, the conductivity type of which may be n-type, a second well region 112, the conductivity type of which may be p-type, a buried layer 121, the conductivity type of which may be p-type, a third well region 213, the conductivity type of which may be n-type, and a fourth well region 114, the conductivity type of which may be p-type, may be formed in said semiconductor substrate, wherein said second well region 112 may form an active metallurgical p-n junction 171 with said first well region 211.

FIG. 16 illustrates a cross-sectional view of a photodetector according to an embodiment. With reference to FIG. 16, a photodetector may be provided, which may include a semiconductor substrate 101. The conductivity type of said semiconductor substrate may be p-type. Analogous to the elements of the photodetector illustrated in FIG. 3, a first well region 211, the conductivity type of which may be n-type, a second well region 112, the conductivity type of which may be p-type, a third well region 213, the conductivity type of which may be n-type, and a fourth well region 114, the conductivity type of which may be p-type, may be formed in said semiconductor substrate, wherein said second well region 112 may form an active metallurgical p-n junction 171 with said first well region 211. In this embodiment, the buried layer of the photodetector illustrated in FIG. 3 may have the same conductivity type and same doping concentration as the semiconductor substrate 101, and is therefore omitted from the drawing.

FIG. 17 illustrates a cross-sectional view of a photodetector according to an embodiment. With reference to FIG. 17, a photodetector may be provided, which may include a first electrode region 231 placed within said first well region 211 and electrically coupled to a first metal contact region 241, in addition to the elements of the photodetector illustrated in FIG. 15. The conductivity type of said first electrode region 231 may be n-type, forming an isotype metallurgical junction with said first well region 211. The doping concentration of said first electrode region 231 may be substantially higher than the doping concentration of said first well region 211.

Said photodetector may further include a second electrode region 132 placed within said fourth well region 114 and electrically coupled to a second metal contact region 142, in addition to the elements of the photodetector illustrated in FIG. 15. The conductivity type of said second electrode region 132 may be p-type, forming an isotype metallurgical junction with said fourth well region 114. The doping concentration of said second electrode region 132 may be substantially higher than the doping concentration of said fourth well region 114.

FIG. 18 illustrates a cross-sectional view of a photodetector according to an embodiment. With reference to FIG. 18, a photodetector may be provided, which may include a first insulating region 151 placed between said first electrode region 231 and said second electrode region 132, and a second insulating region 152, extending laterally from said second electrode region 132 towards said semiconductor substrate 201, in addition to the elements of the photodetector illustrated in FIG. 15. The material of said insulating regions 151 and 152 may be, but is not limited to, silicon dioxide.

Applying a positive bias voltage between said first contact region 241 and said second contact region 142 may result in a reverse bias voltage between elements having a p-type conductivity (112, 114, 121 and 132) and elements having an n-type conductivity (211, 213, and 231), which may result in an active depletion region being formed between said first electrode region 231 and said buried layer 121. Said active depletion region may extend from the bottom of said first electrode region 231 to the top of said buried layer 121 and may provide a layer having a function of absorbing incident light. Photons absorbed above said active metallurgical p-n junction 171 may generate electron-hole pairs, where the photogenerated holes may drift towards said active metallurgical p-n junction under the influence of the electric field within said active depletion region. The same may apply to thermally generated holes. Photons absorbed below said active metallurgical p-n junction 171 may generate electron-hole pairs, where the photogenerated electrons may drift towards said active metallurgical p-n junction under the influence of the electric field within said active depletion region. The same may apply to thermally generated electrons.

Applying a high enough positive bias voltage between said first contact region 241 and said second contact region 142 may result in avalanche multiplication of charge carriers in the vicinity of the electric field maximum positioned near said active metallurgical p-n junction 171. The applied negative bias voltage may result in a reverse bias voltage higher than the breakdown voltage of said active metallurgical p-n junction, and said photodetector may operate in Geiger mode.

With reference to FIG. 18, analogous to the simulated avalanche probability due to the multiplication of electrons and holes within the central regions of SPAD B, illustrated in FIG. 9, said photodetector may feature a wide region having a high avalanche probability for electrons, below said electric field maximum. Electrons generated within said high-avalanche-probability region may cause the majority of avalanche multiplication events under illumination with a long-wavelength light having a long penetration depth. For a semiconductor material wherein the ionization coefficient for electrons is substantially higher than the ionization coefficient for holes (e.g., monocrystalline silicon), this may result in a substantially higher PDP compared with SPAD B at said long wavelength. For a semiconductor material wherein the ionization coefficient for electrons is substantially lower than the ionization coefficient for holes, this may result in a low PDP at said long wavelength. However, holes may still cause the majority of avalanche multiplication events under illumination with a short-wavelength light having a short penetration depth from said top surface, which may result in a high PDP at said short wavelength. Electrons thermally generated within said high-avalanche-probability region may also cause the majority of avalanche multiplication events in the absence of light. For a semiconductor material wherein the ionization coefficient for electrons is substantially higher than the ionization coefficient for holes (e.g., monocrystalline silicon), this may result in a substantially higher DCR compared with SPAD B. For a semiconductor material wherein the ionization coefficient for electrons is substantially lower than the ionization coefficient for holes, this may result in a low DCR.

FIG. 19 illustrates a cross-sectional view of a photodetector according to an embodiment. With reference to FIG. 19, a photodetector may be provided, which may include a layered structure region 261 formed on said top surface between said first electrode region 231 and said second electrode region 132, in addition to the elements of the photodetector illustrated in FIG. 18. Said layered structure region 261 may comprise, but is not limited to, a polycrystalline silicon layer on top of a silicon dioxide layer. Said layered structure region 261 may be electrically coupled to said first electrode region 231. Said first insulating region 151 may be removed beneath said layered structure region 261.

With reference to FIG. 14, elements of said photodetector may be manufactured using a well-established high-voltage CMOS technology, simultaneously with CMOS transistors, on an n-type monocrystalline silicon substrate 201. Said first electrode region 231 may be manufactured as an n+ source/drain region, said second electrode region 132 may be manufactured as a p+ source/drain region, said first well region 211 may be manufactured as a medium-voltage n-well region (e.g., a 5-V n-well region in a 180 nm high-voltage CMOS technology with a nominal supply voltage of 1.8 V), said second well region 112 may be manufactured as a high-voltage p-well region, said buried layer 121 may be manufactured as a p-type buried layer, said third well region 213 may be manufactured as a high-voltage n-well region, said fourth well region 114 may be manufactured as a high-voltage p-well region, said insulating regions 151 and 152 may be manufactured as shallow trench isolation (STI) regions, and said layered structure region 261 may be manufactured as a gate polycrystalline silicon layer on top of a gate oxide layer, all being part of said high-voltage CMOS technology method of manufacturing. Said first contact region 241 and said second contact region 142 may be electrically coupled to a metal layer being part of said high-voltage CMOS technology method of manufacturing.

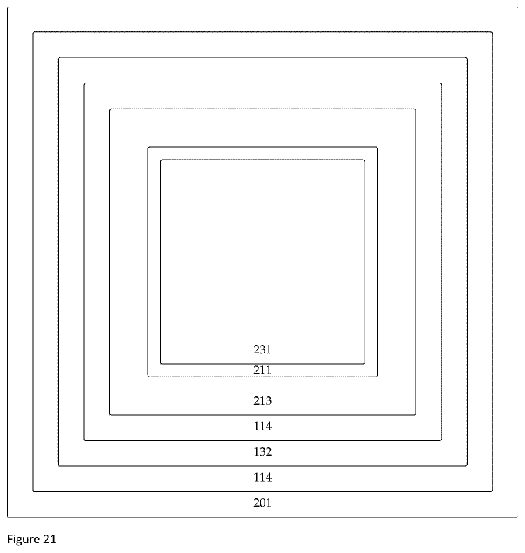

FIG. 20 illustrates a plan view of the photodetector from FIG. 17 according to an embodiment. With reference to FIG. 20, said first well region 211 and said first electrode region 231 may have a circular shape, whereas said third well region 213, said fourth well region 114 and said second electrode region 132 may have a circular annular shape.

FIG. 21 illustrates a plan view of the photodetector from FIG. 17 according to an embodiment. With reference to FIG. 21, said first well region 211 and said first electrode region 231 may have a square shape, whereas said third well region 213, said fourth well region 114 and said second electrode region 132 may have a square annular shape.

Analogous to the elements of the photodetectors illustrated in FIGS. 13-14 and FIGS. 20-21, said first well region and said first electrode region may have a different shape (e.g., rectangular, octagonal, elliptical, rectangular with round corners, or any other shape), whereas said second well region, said third well region and said second electrode region may have a different annular shape (e.g., rectangular, octagonal, elliptical, rectangular with round corners, or any other shape).

1. A photodetector, comprising:
a semiconductor substrate having a top surface, a substrate conductivity type and a substrate doping concentration;
a first well region having a first conductivity type, extending into said semiconductor substrate to a first depth from said top surface;
a second well region having a second conductivity type, extending into said semiconductor substrate from said first depth to a second depth from said top surface, said second depth being larger than said first depth, forming a first active metallurgical p-n junction with said first well region; and
a buried layer having a second conductivity type, substantially distant from said top surface, forming a first isotype metallurgical junction with said second well region at a distance D from said top surface, said distance D being larger than said first depth;
wherein said first active metallurgical p-n junction produces a built-in electric field, said electric field having a depth-dependent intensity profile and said electric field profile having a maximum positioned between 0.2D and 0.8D when measured from said top surface.

2. The photodetector of claim 1, further comprising:
a third well region having a first conductivity type, extending into said semiconductor substrate to a third depth from said top surface, said third depth being larger than said first depth, wherein said third well region surrounds and overlaps with a portion of said first well region, forming a first passive metallurgical p-n junction with said buried layer, and forming a second passive metallurgical p-n junction with said second well region, said second passive metallurgical p-n junction being substantially perpendicular to said top surface; and
a fourth well region having a second conductivity type, extending into said semiconductor substrate to a fourth depth from said top surface, said fourth depth being larger than said first depth, wherein said fourth well region surrounds said third well region, forming a second isotype metallurgical junction with said buried layer, and forming a third passive metallurgical p-n junction with said third well region, said third passive metallurgical p-n junction being substantially perpendicular to said top surface.

3. The photodetector of claim 1, wherein said buried layer has the same conductivity type as said substrate conductivity type and has a doping concentration substantially equal to said substrate doping concentration.

4. The photodetector of claim 2, further comprising:
a first electrode region having a first conductivity type, extending into said semiconductor substrate from said top surface, placed within said first well region and electrically coupled to a first contact region, wherein said first electrode region has a substantially higher doping concentration than said first well region;
a second electrode region having a second conductivity type, extending into said semiconductor substrate from said top surface, placed within said fourth well region and electrically coupled to a second contact region, wherein said second electrode region has a substantially higher doping concentration than said fourth well region.

5. The photodetector of claim 4,
wherein a depletion region is formed between said first electrode region and said buried layer, providing a layer having a function of absorbing incident light, and wherein said first active metallurgical p-n junction produces an electric field which provides multiplication of charge carriers generated within said depletion region.

6. The photodetector of claim 4,
wherein an insulating region extending into said semiconductor substrate from said top surface is placed between said first electrode region and said second electrode region; and
wherein a layered structure region is formed on said top surface between said first electrode region and said second electrode region.

7. The photodetector of claim 6,
wherein said semiconductor material is monocrystalline silicon;
wherein said insulating region material is silicon dioxide; and
wherein said layered structure region comprises a polycrystalline silicon layer on top of an insulating layer.

8. The photodetector of claim 7, wherein said first electrode region and said second electrode region are manufactured, using a high-voltage CMOS technology, as source/drain regions.

9. The photodetector of claim 7, wherein said first well region is manufactured, using a high-voltage CMOS technology, as a medium-voltage well region.

10. The photodetector of claim 7, wherein said second well region, said third well region and said fourth well region are manufactured, using a high-voltage CMOS technology, as high-voltage well regions.

11. The photodetector of claim 7, wherein said buried layer is manufactured, using a high-voltage CMOS technology, as a buried layer.

12. The photodetector of claim 7, wherein said insulating region is manufactured, using a high-voltage CMOS technology, as a shallow trench isolation (STI) region.

13. The photodetector of claim 7, wherein said layered structure region is manufactured, using a high-voltage CMOS technology, as a gate polycrystalline silicon layer on top of a gate oxide layer.

14. A photodetector manufactured using a high-voltage CMOS technology, the photodetector comprising:
a monocrystalline silicon substrate having a top surface, a substrate conductivity type and a substrate doping concentration;
a medium-voltage well region having a first conductivity type, extending into said semiconductor substrate to a first depth from said top surface;
a first high-voltage well region having a second conductivity type, extending into said semiconductor substrate from said first depth to a second depth from said top surface, said second depth being larger than said first depth, forming a first active metallurgical p-n junction with said medium-voltage well region; and
a buried layer having a second conductivity type, substantially distant from said top surface, forming a first isotype metallurgical junction with said first high-voltage well region at a distance D from said top surface, said distance D being larger than said first depth;
wherein said first active metallurgical p-n junction produces a built-in electric field, said electric field having a depth-dependent intensity profile and said electric field profile having a maximum between 0.2D and 0.8D when measured from said top surface, and
wherein said photodetector is characterized by a Dark Count Rate (DCR) lower than 0.25 Hz per micrometer square at an excess voltage of 5 V and at a temperature of 300 K.

15. The photodetector of claim 14, further comprising:
a second high-voltage well region having a first conductivity type, extending into said semiconductor substrate to said second depth from said top surface, wherein said second high-voltage well region surrounds and overlaps with a portion of said medium-voltage well region, forming a first passive metallurgical p-n junction with said buried layer, and forming a second passive metallurgical p-n junction with said first high-voltage well region, said second passive metallurgical p-n junction being substantially perpendicular to said top surface; and
a third high-voltage well region having a second conductivity type, extending into said semiconductor substrate to said second depth from said top surface, wherein said third high-voltage well region surrounds said second high-voltage well region, forming a second isotype metallurgical junction with said buried layer, and forming a third passive metallurgical p-n junction with said second high-voltage well region, said third passive metallurgical p-n junction being substantially perpendicular to said top surface.

16. The photodetector of claim 14, wherein said buried layer has the same conductivity type as said substrate conductivity type and has a doping concentration substantially equal to said substrate doping concentration.

17. The photodetector of claim 15, further comprising:
a first source/drain region having a first conductivity type, extending into said semiconductor substrate from said top surface, placed within said medium-voltage well region and electrically coupled to a first contact region; and
a second source/drain region having a second conductivity type, extending into said semiconductor substrate from said top surface, placed within said third high-voltage well region and electrically coupled to a second contact region.

18. The photodetector of claim 17, wherein a depletion region is formed between said first source/drain region and said buried layer, providing a layer having a function of absorbing incident light, and wherein said first active metallurgical p-n junction produces an electric field which provides multiplication of charge carriers generated within said depletion region.

19. The photodetector of claim 17, wherein a shallow trench isolation (STI) region extending into said semiconductor substrate from said top surface is placed between said first source/drain region and said second source/drain region.

20. The photodetector of claim 17, wherein a gate polycrystalline silicon layer on top of a gate oxide layer is formed on said top surface between said first source/drain region and said second source/drain region.
